(19) United States
(12) Patent Application Publication
(10) Pub. No.: US 2007/0080056 A1
(43) Pub. Date: Apr. 12, 2007

(54) Method and apparatus for cylindrical magnetron sputtering using multiple electron drift paths

(76) Inventors: John R. German, Prairie Du Sac, WI (US); Klaus H. Hartig, Avoca, WI (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 11/245,651

(22) Filed: Oct. 7, 2005

(51) Int. Cl. C23C 14/32; C23C 14/00

(52) U.S. Cl. 204/192.1; 204/298.16

(57) ABSTRACT

A cylindrical cathode target assembly for use in sputtering target material onto a substrate comprises a generally cylindrical target, means for rotating the target about its axis during a sputtering operation, a magnetic array carried within the target for generation of a plasma-containing field including a plurality of electron drift paths adjacent an outer surface of the target, and a device for supporting the magnetic array independently of rotation of the target. In certain embodiments of the invention, the magnetic array may include a plurality of magnetic elements arranged to form a plurality of electron drift paths spaced along a substantial length of the target to promote generally uniform film deposition and uniform target utilization along its length.

### FIELD OF THE INVENTION

The invention relates to a system and apparatus for depositing films on surfaces, and more particularly to a method and apparatus for reducing or eliminating non-uniformities and variations in deposited film thickness during magnetron sputtering operations.

### BACKGROUND

A variety of methods exist to apply coatings, such as thin films, to substrates, such as glass. Generally, sputtering is a technique for forming a thin film on a substrate. Sputtering techniques include diode DC sputtering, triode sputtering, and magnetron sputtering.

Magnetron sputtering has become a widely used sputtering technique. Films formed by sputtering can be important for numerous devices, such as semiconductors and window glass. Typical films created by these processes include metallic materials such as silver, aluminum, gold, and tungsten, or dielectric materials such as zinc oxide, tin oxide, titanium oxide, silicon oxide, silicon nitride, and titanium nitride. Magnetron sputtering involves providing a target, including or formed of a metal or dielectric material, and exposing this target to a plasma in a deposition chamber. Ions formed in the plasma may be accelerated toward the target due to the presence of an electric field. Momentum from this ion bombardment is transferred to atoms on the target's surface, thereby causing atoms of the target to gain enough energy to leave the surface of the target. Some of the atoms that have been rejected from the surface of the target in this manner are deposited on a substrate, thereby providing thin, uniform coating layers on substrates.

The gas used to form the plasma may be an inert, non-reacting gas, such as argon. Alternately, or additionally, reactive gases, such as nitrogen or oxygen, may be used to form the plasma. Reactive gases may combine with sputtered atoms during the formation of the sputtered coating. Deposition of reacted compounds, such as zinc oxide, tin oxide, etc., may be achieved in this manner.

To improve the efficiency of the sputtering process (i.e., to improve sputtering rate), the number of available ions may be increased by increasing the density of the plasma. To obtain a high density plasma, an electric field and a magnetic field may be used together to produce a resultant force on electrons that tends to keep the electrons in a region near the surface of the target (i.e., the“plasma-containing region,” or“confinement region”). The resultant force on electrons in such a region is governed by the vector cross product of the electric and magnetic fields (the“E×B” drift path). For example, a magnetic field may be formed such that the magnetic lines of flux are in a direction that is generally parallel to the surface of the target. An electric field may be provided (e.g., by applying a voltage to the target) to accelerate electrons in a direction perpendicular to the surface of the target. The resultant force on the ions is defined by the“E×B” drift path and is in a direction perpendicular to both the electric and magnetic fields, governed by the“right hand rule.” This force on the electrons results in“electron drift paths,” which may be used to keep the electrons near the surface of the target, where they may collide with other neutral atoms or molecules (from the plasma or sputtered atoms from the target), thereby causing further ionizations and increasing the sputtering rate.

The magnetic fields used in sputtering magnetrons are typically provided by placing one or more magnets behind the target to help shape the plasma and focus the plasma in an area adjacent the surface of the target (i.e., the“confinement region”). The magnetic field lines may, for example, emanate from a magnet (or magnets) placed behind the target, penetrating through and forming arcs over the target surface such that the magnetic field lines are substantially parallel to the target surface. The plasma may be concentrated near the surface of the target by wrapping and joining the magnetic field lines upon themselves to form a closed-loop“racetrack” pattern. This can be done, for example, with appropriately sized and shaped magnetic elements. A“planar magnetron” configuration is shown in FIGS. 1 (a) and (b) illustrating racetrack-shaped plasma-containing electron drift paths.

Planar magnetrons tend to develop racetrack-shaped grooves eroded into the targets, caused by continued sputtering in a racetrack pattern that is largely static relative to the target. Erosion is strongest near the center of the path formed by the magnets (due to the increased confinement of plasma in this area), which tends to create a“V-shaped” racetrack groove in the target surface. As the groove deepens, uniformity of the film being deposited tends to get worse and sputtering rates tend to decline. The utilization of target material is typically quite low for planar magnetrons as a result, with target utilization in some cases falling in the range of about 15% to 30% of total target volume.

A cylindrical magnetron target assembly is shown in a partial cut-away perspective view in FIG. 2. The target material of the cylindrical target 30 is shaped like a tube and is adapted to be rotated about its axis with a magnet assembly 80 located inside the cylindrical target 30. The magnet assembly 80 does not normally rotate about the axis of the target; rather, it is commonly held in a fixed position relative to the rotating cylindrical target. The magnets in a cylindrical magnetron typically form narrow racetracks extending substantially the length of the cylindrical target. Cylindrical magnetrons help address the problem of low target material utilization by rotating the cylindrical target relative to the magnet assembly, thereby lessening the effects of racetrack grooving found in planar magnetron target assemblies. The rotating surface reduces surface erosion grooving and can result in target utilization greater than 80%.

Although rotation of the cylindrical magnetron targets improves target utilization, it has been difficult to simultaneously optimize target utilization and sputtering uniformity. If, on the one hand, the confinement field at the turnarounds is substantially the same strength as along the straight portions, then excess target erosion occurs at the turnarounds. This is because a point of the target that rotates tangentially through the arc of the turnaround spends more time in the high-density portion of the plasma than do points that rotate perpendicularly through the straight portions of the racetrack. A common method to improve target utilization is to weaken the magnetic confinement at the turnaround in order to compensate for the excess time a point spends in the plasma at said turnaround. However, the weakened magnetic confinement leads to electron losses and changes in the drift velocity which, in turn, result in spatial variations of plasma density and hence non-uniform sputtering rate. These effects are not immediately self-correcting and extend well beyond the immediate vicinity of the turnaround. So even though the turnaround may be away from the substrate, non-uniform deposition on the substrate may result from issues at each turnaround.

The result of uneven erosion patterns is that by the time the target must be replaced due to nearly complete erosion near the target ends, the central portion of the target still retains a substantial amount of sputterable target material. Better target utilization is desirable to minimize waste of target material. Moreover, replacing used targets is a time-consuming and expensive operation, typically requiring the sputtering line to be shut down for a significant period of time.

### SUMMARY OF THE INVENTION

In certain embodiments of the invention, a cathode target assembly for use in sputtering target material onto a substrate includes a generally cylindrical target and a magnetic array, the magnetic array adapted to provide a plasma confinement region adjacent an outer surface of the target comprising a plurality of electron drift paths along the length of the target. In certain embodiments, the magnetic array, or portions thereof, may be further adapted to oscillate generally axially with respect to the cylindrical target in order to further promote efficient target utilization along the length of the target.

In certain other embodiments of the invention, a magnetic array for generating a plasma-confinement region during sputtering operations may include a plurality of magnetic elements adapted to be disposed within a cylindrical target to provide a plurality of magnetic flux loops along a length of the cylindrical target.

In an alternate embodiment of the invention, a magnetic array for generating a plasma-confinement region during sputtering operations may include a magnetic element adapted to be disposed within a cylindrical target to provide a generally serpentine-shaped magnetic flux loop along a substantial length of the cylindrical target.

In certain embodiments of the invention, a method of sputtering material from a cylindrical cathode target may include: providing a deposition chamber having a cathode target assembly and a conveyor for moving a substrate through the deposition chamber in proximity to the cylindrical cathode target of the cathode target assembly; forming a plurality of plasma-containing confinement regions along a length of the cylindrical cathode target; rotating the cylindrical cathode target relative to a magnetic array disposed within the cylindrical cathode target; and moving the substrate through the deposition chamber in proximity to the cylindrical cathode target, wherein the magnetic array comprises a plurality of magnetic elements adapted to provide a plurality of magnetic flux loops along a length of the cylindrical cathode target.

### DESCRIPTION OF THE DRAWINGS

FIGS. 1 (a) and (b) are schematic representations of the formation of electron drift path “racetracks” used in a planar magnetron sputtering process.

FIG. 2 is a partial cut-away perspective view of a cylindrical magnetron target assembly in accordance with an embodiment of the invention.

FIG. 3 is a cut-away front view of a cylindrical magnetron configuration in accordance with an embodiment of the invention.

FIG. 4 is a schematic bottom view of a cylindrical magnetron configuration, showing a representation of an electron drift path“racetrack” pattern.

FIG. 4 (a) is a schematic planar projection of a dual race-track electron drift path configuration.

FIG. 5 is a schematic planar projection of a plurality of electron drift paths formed by a magnetic array assembly disposed in a cylindrical target according to an embodiment of the invention.

FIG. 6 is a schematic perspective view of a magnetic array assembly disposed within a cylindrical target in accordance with one embodiment of the invention.

FIG. 7 is a schematic planar projection of a plurality of electron drift paths formed by a magnetic array assembly disposed in a cylindrical target according to an embodiment of the invention.

FIG. 8 is a schematic planar projection of a plurality of electron drift paths formed by a magnetic array assembly disposed in a cylindrical target according to an embodiment of the invention.

FIG. 9 is a schematic planar projection of a plurality of electron drift paths formed by a magnetic array assembly disposed in a cylindrical target according to an embodiment of the invention.

FIG. 10 is a schematic planar projection of a plurality of electron drift paths formed by a magnetic array assembly disposed in a cylindrical target according to an embodiment of the invention.

FIG. 11 is a schematic planar projection of an electron drift path formed by a magnetic array assembly disposed in a cylindrical target according to an embodiment of the invention.

FIG. 12 is a cross-sectional side view of a deposition chamber which may be used to sputter target material onto a surface of a substrate according to an embodiment of the invention.

FIG. 13 is a cross-sectional side view of a deposition chamber which may be used to sputter target material onto a surface of a substrate according to an embodiment of the invention.

FIG. 14 is a cross-sectional side view of a deposition chamber which may be used to sputter target material onto a surface of a substrate according to an embodiment of the invention.

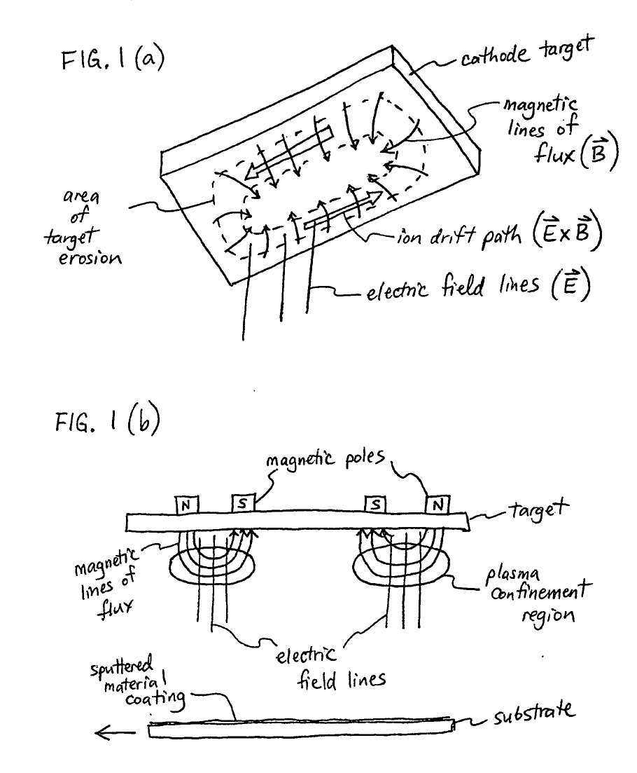

### DETAILED DESCRIPTION

The following detailed description should be read with reference to the drawings, in which like elements in different drawings are numbered identically. The drawings depict selected embodiments and are not intended to limit the scope of the invention. It will be understood that embodiments shown in the drawings and described below are merely for illustrative purposes, and are not intended to limit the scope of the invention as defined in the claims.

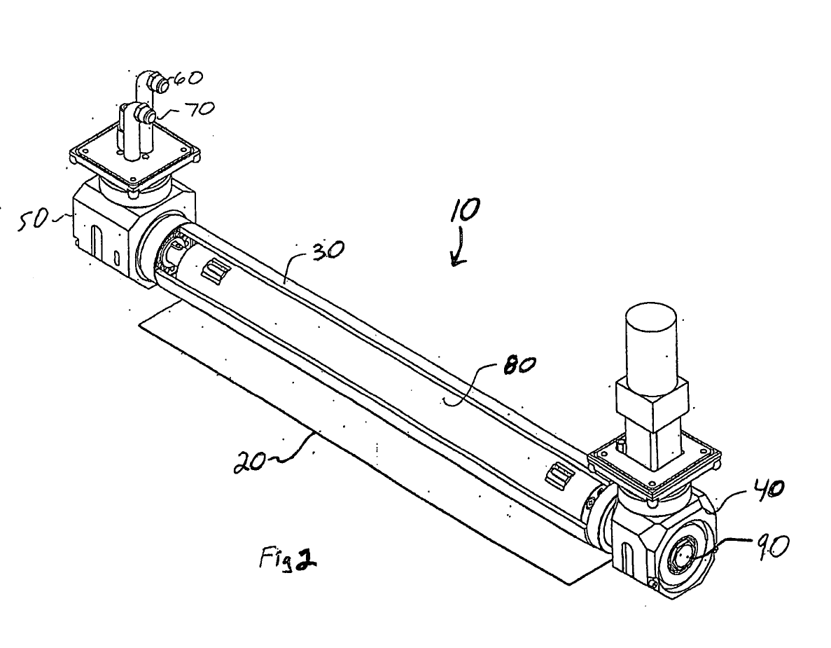

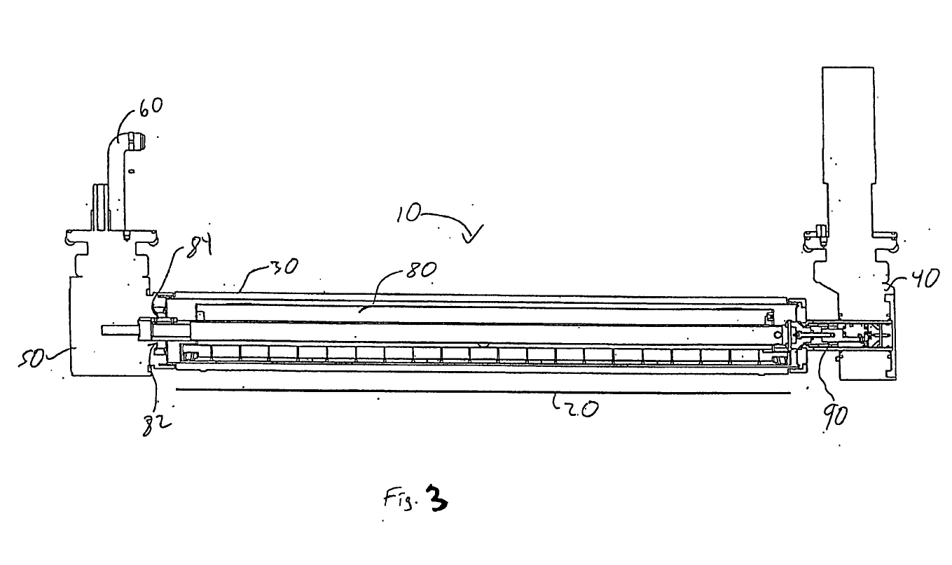

FIGS. 2 and 3 show a rotatable cathode target assembly in accordance with an embodiment of the present invention. During a sputtering process, the cathode target assembly 10 may be used for coating a substrate 20 with material from a cylindrical target 30 of the assembly. Examples of materials which may form at least part of the cylindrical target 30 and can be sputtered include metals, for example, silver, aluminum, gold, chromium, copper, nickel, zinc, tin, titanium, and niobium. Compounds of various metals, such as nickel-chromium, can be sputtered using targets made of the desired compound. Silicon can also be used as cylindrical target material, for example, by plasma spraying silicon onto a support tube.

Cylindrical target 30 preferably is rotatable about its longitudinal axis, typically by means of a motor (e.g., an electric motor) or other such motive device. In some embodiments, the motive device/rotating means comprises a drive end block 40 containing a motor suitable for rotating cylindrical target 30. Cathode target assembly 10 may be provided with a support end block 50, which may be suitable for supporting the cylindrical target 30 opposite the drive end block 40. In some embodiments, support end block 50 houses a cooling fluid inlet 60 and a cooling fluid outlet 70. Cooling fluid inlet 60 and cooling fluid outlet 70 may provide cooling water to cylindrical target 30 to cool it during the sputtering process. Alternatively, cathode target assembly 10 may be cantilevered, and may not include a support end block 50.

The cathode target assembly 10 includes a magnetic array assembly 80 carried within the cylindrical target 30 for generation of a plasma confinement field adjacent a surface of the target 30. The magnetic array assembly 80 may be disposed within cylindrical target 30 (e.g., within an interior recess bounded by the cylindrical target). A framework 82 (or similar support means) may be provided for supporting the magnetic array assembly 80, optionally independently of rotation of the target 30 (e.g., in a static, or substantially static, state). In the embodiment shown in FIG. 3, for example, the framework 82 includes a key 84. Key 84 may be adapted to prevent the magnetic array assembly 80 from rotating during rotational movement of the target 30 (i.e., independently of rotation of the target 30) using conventional methods known in the art.

Framework 82 and key 84 may additionally be adapted to allow movement of the magnetic array assembly 80, or portions thereof, in a direction generally along the longitudinal axis of the target 30, according to certain embodiments of the invention.

A variety of substrates are suitable for use in the present invention. In most cases, the substrate is a sheet of transparent material (i.e., a transparent sheet). However, the substrate is not required to be transparent. For example, opaque substrates may be useful in some cases.

However, it is anticipated that for most applications, the substrate will comprise a transparent or translucent material, such as glass or clear plastic. In many cases, the substrate will be a glass sheet. A variety of known glass types can be used, and soda-lime glass is expected to be preferred.

Substrates of various size can be used in the present invention. For example, the invention can be used to process large-area substrates. Certain embodiments of the invention can process a substrate having a width of at least about .5 meter, preferably at least about 1 meter, perhaps more preferably at least about 1.5 meters (e.g., between about 2 meters and about 4 meters), and in some cases at least about 3 meters.

Substrates of various thickness can also be used with certain embodiments of the invention.

Commonly, substrates with a thickness of about 1-5 mm are used. Some embodiments involve a substrate with a thickness of between about 2.3 mm and about 4.8 mm, and perhaps more preferably between about 2.5 mm and about 4.8 mm. In some cases, a sheet of glass (e.g., soda-lime glass) with a thickness of about 3 mm is used.

The invention is particularly advantageous in processing large area substrates, such as glass sheets for architectural and automotive glass applications. Substrates of this nature commonly have a width of at least about .5 meter, more commonly at least about one meter, and typically greater than about 1.5 meters (e.g., between about 2 meters and about 4 meters). Accordingly, the target is preferably adapted to sputter target material substantially across the entire width of such a substrate (i.e., a substrate having a width in one or more of the above ranges). With large area substrates in particular (especially those formed of glass), it is desirable to convey the substrates through a deposition chamber in a horizontal orientation, rather than in a vertical orientation.

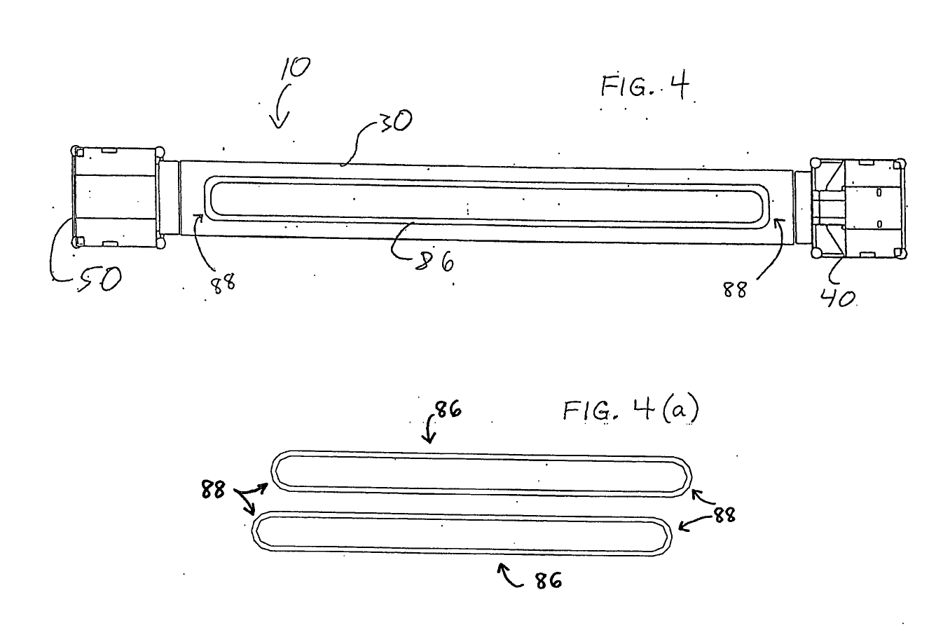

FIG. 4 shows a target wear pattern 86 on a cylindrical target 30 formed by erosion due to sputtering along a single racetrack-shaped electron drift path. Although rotation of the cylindrical target 30 about its axis during sputtering operations improves target utilization, the turnaround portions 88 of the wear pattern 86 typically cause more sputtering to occur at the ends of the cylindrical target 30 near the turnaround portions 88 and hence, non-uniform erosion near the turnaround portions 88 may persist. Thus, the end regions of cylindrical target 30 may become depleted of sputterable target material to an extent which may require replacement of the cylindrical target 30, while the central portion of the target may still have significant amounts of sputterable target material remaining; this may result in wasted target material.

FIG. 4 (a) shows an example of a dual race-track electron drift path arrangement that has been used to attempt to address the above-noted problem. However, many of the same problems still persist, at least to some extent, perhaps due in part to the continuing presence of the turn-around portions. It should be noted that the racetrack configurations depicted in the drawing figures that follow are schematic“planar projections” of the electron drift paths and/or magnetic elements unless otherwise noted. That is, the figures are“flattened out” to facilitate illustration. By contrast, FIG. 6 (described in more detail below) is an example of a schematic perspective view of magnetic elements positioned within a cylindrical target, illustrating one example of how certain magnetic elements can be shaped and contoured to fit within a cylindrical target.

Certain embodiments of the invention provide a magnetic array assembly 80 within (e.g., mounted within an axially-extending central cavity defined by) a cylindrical target 30 for generating a plurality (at least two, in some cases at least three, optionally at least five, or even at least seven) of electron drift paths arranged to simultaneously improve film deposition uniformity and target utilization. By providing a number of smaller electron drift paths along the length of the target (optionally having their respective centers maintained at longitudinally spaced-apart locations), rather than one long“racetrack”-shaped electron drift path, the magnetic field distribution, and hence, the overall plasma confinement field, is substantially similar in strength and structure along the length of the target, regardless of non-uniformities that may be present in the individual electron drift paths, when considering the averages over short distances. The plasma confinement fields present near the ends of the target are not substantially different from those along the central length of the target. Although there may be a periodic variation in sputter rate along the target length, the multiple distributions of the flux of sputtered material results in more uniform erosion of target material. Further improvements in uniformity of erosion, and hence, in target utilization, may be achieved by the additional use of magnet-bar oscillators, which periodically shift the magnets a small distance with respect to the target. If the periodic variation of the confinement results in periodic variation in film deposition, film deposition can be further improved by using a plurality of sputtering targets, wherein the magnetic arrays per the invention, are in slightly different positions in each target so that the average film, deposited by the plurality of targets, is even more uniform.

The use of multiple electron drift paths along the length of a cylindrical cathode target may be particularly useful when reactive gases (e.g., comprising oxygen and/or nitrogen) are used in the sputtering process. During sputtering operations in which reactive gases are used, the problem of non-uniform deposition rates near the ends of a target may be compounded, particularly when operating in the transition between metal-mode and full poisoned mode. The regions of more intense plasma (usually at the ends of the target) sputter faster than low-intensity regions, thus more quickly consuming the reactive gas making the high intensity regions more metallic. The more metallic regions, in turn, have an even higher sputter rate. The interaction is very non-linear and results not only in variations of deposition rate, but also causes variations in film stoichiometry.

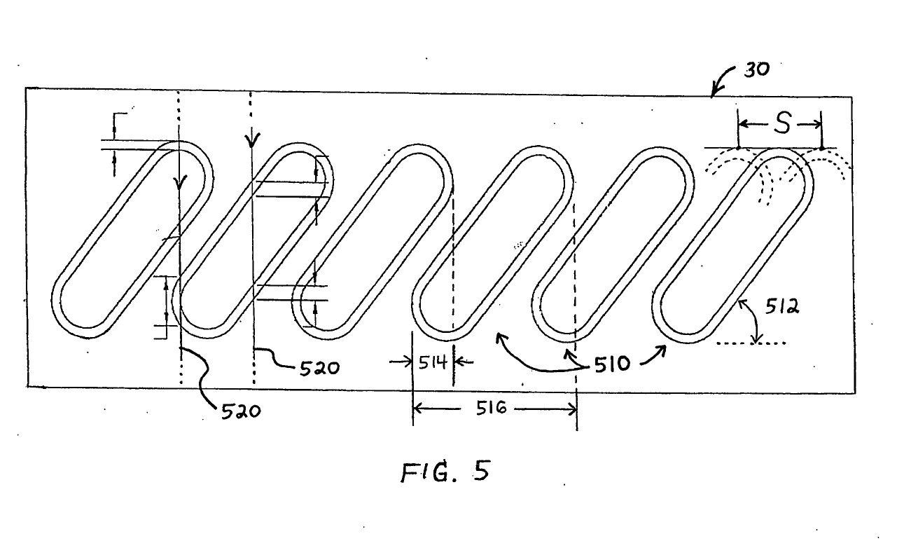

FIG. 5 shows a planar projection of a plurality of electron drift paths 510 formed by a magnetic array assembly 80 (shown in FIG. 6) disposed within a cylindrical target 30 in accordance with an embodiment of the invention. This exemplifies embodiments wherein the magnetic array assembly is adapted to create (and, when used, creates) a plurality of (e.g., at least two, at least three, or even at least five) electron drift paths each having a generally oval configuration. The number of drift paths in such embodiments is by no means limiting to the invention. The embodiment shown in FIG. 5 includes six generally oval electron drift paths 510 spaced along a length of a cylindrical target. Preferably, the oval-shaped drift paths are not arranged so that their long dimensions are simply parallel to the longitudinal axis of the cylindrical target. Rather, the ovals preferably have their long dimensions arranged so as to be at an oblique angle relative to the noted target axis (optionally by at least five degrees, or perhaps at least ten degrees, and in some embodiments, between about 15 and about 85 degrees). (As shown in FIG. 5, a point (i.e., a longitudinal location) on the target during target rotation defines a target rotational path 520. Two such target rotational paths 520 are illustrated in FIG. 5. In the embodiment illustrated in FIG. 5, each electron drift path 510 is oriented (e.g., is elongated in a direction extending) at an oblique angle 512 relative to a longitudinal axis of cylindrical target 30. Oblique angle 512 preferably is an acute angle, optionally one ranging from 1 to 89 degrees, such as between 20 and 70 degrees according to certain embodiments of the invention. The invention provides a variety of embodiments (wherein optionally there is provided at least five total electron drift paths) wherein at least one such generally oval electron drift path is formed, optionally together with other electron drift paths that have different configurations.

In certain embodiments of the invention, a portion of an electron drift path 510 may overlap a portion of an adjacent electron drift path 510 to define an overlapping region 514. In this context, the term overlap means that portions of two drift paths are located at the same longitudinal locale (i.e., are the same distance from a given end 30E of the target) on the target. Thus, a target rotational path 520 that falls within an overlapping region 514 will cross multiple (i.e., at least two) electron drift paths 510 during rotation of the target 30 relative to the magnetic array assembly 80. The amount of overlap may be defined in a number of ways, as would be appreciated by one of ordinary skill in the art. For example, one might define a“percent overlap” to be the length of an overlapping region 514 divided by the longitudinal electron drift path displacement 516, as shown in FIG. 5, the result being multiplied by 100%. In general, the calculated percent overlap may be varied to accommodate a desired application by selecting any percent overlap value between 1% and 99%, and may commonly range from about 2% to about 50%, perhaps optimally between about 5% and about 40%. In one particular embodiment, the percent overlap is between about 10% and about 35%.

In certain embodiments of the invention, the oblique angle 512 and the amount of overlap may be chosen such that an area of relatively high erosion rate on one drift path 510 falls along the same target rotational path 520 as an area of relatively low erosion rate of a nearby or adjacent drift path 510 to provide more uniform target depletion.

FIG. 6 shows a layout perspective view of a magnetic array assembly 80 disposed within a cylindrical cathode target 30 according to one embodiment of the invention. The illustrated magnetic array assembly 80 is comprised of a plurality of magnetic elements 540. The magnetic array assembly 80 of FIG. 6 can, for example, be used to form the electron drift paths 510 illustrated in FIG. 5. With continued reference to FIG. 5, each magnetic element 540 can be comprised of an inner portion 542, having one polarity, and an outer portion 544, having the opposite polarity. The inner portions 542 are shaded in FIG. 6 to indicate they are of one magnetic polarity (e.g.,“north”), while the outer portions 544 are unshaded, indicating they are of a second, opposite polarity (e.g.,“south”). Here, the illustrated outer portion generally surrounds the inner portion. Magnetic lines of flux will therefore extend between the inner and outer portions 542, 544, forming magnetic flux“loops” therebetween. (Magnetic flux loops are sometimes also referred to as“closed field drift paths.”) As shown in FIG. 6, magnetic array assembly 80 is adapted to be placed within a cylindrical cathode target 30 to produce magnetic lines of flux that extend through and have portions that are generally parallel to an outer surface of the cylindrical target 30, forming a plurality of magnetic flux loops disposed along a length of the cylindrical target 30. The magnetic flux loops in some embodiments have their respective centers spaced apart longitudinally from one another. In some cases, each pair of adjacent flux loops have their respective centers spaced apart longitudinally by at least about 0.125 inch, perhaps more preferably at least about 0.5 inch, such as at least about 1 inch, or even at least about 1.5 inches. Any of the spacing distances noted in this paragraph can be provided for other embodiments of the invention, and the flux loops may be oval, circular, rectangular, irregularly shaped, or combinations thereof.

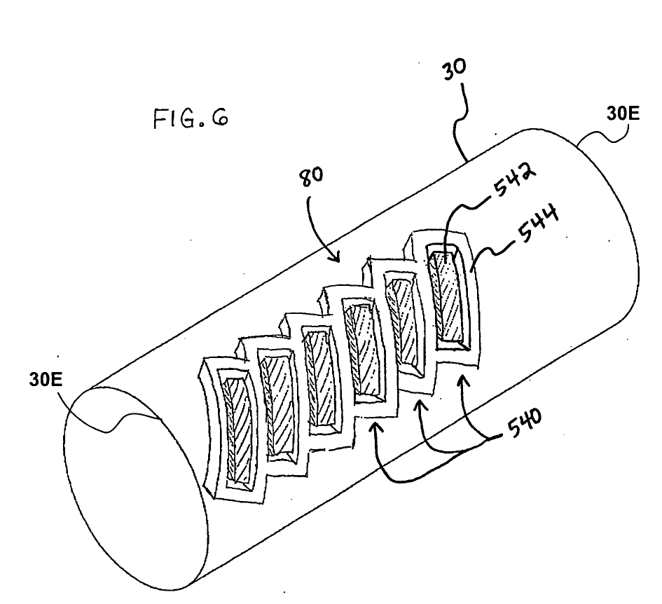

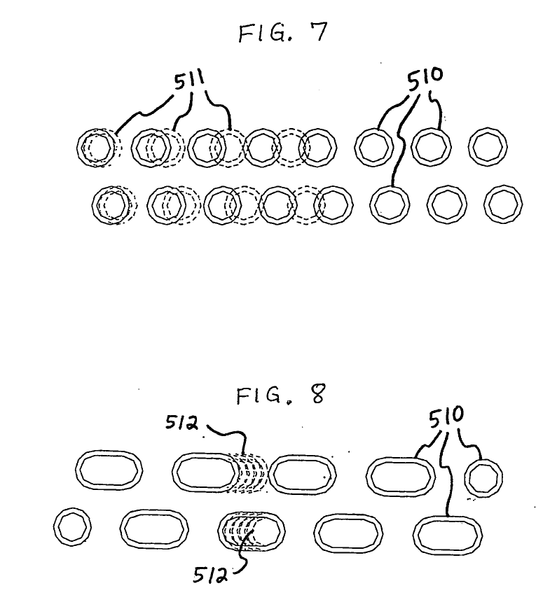

FIG. 7 is a planar projection of a plurality of electron drift paths 510 formed by a magnetic array assembly 80 disposed in a cylindrical target 30 according to one embodiment of the invention. The plurality of electron drift paths 510 in the exemplary embodiment of FIG. 7 comprises two rows of generally circular electron drift paths 510 disposed along a length (each such row optimally spanning at least 50%, perhaps optimally at least about 75%, of the target's total length) of a cylindrical target 30. The magnetic array assembly 80 associated with the embodiment of FIG. 7 can optionally be adapted to move (e.g., oscillate) generally longitudinally with respect to the cylindrical target 30 in order to further promote uniform deposition of target material. For example, the magnetic array assembly 80 may be adapted to move generally longitudinally a distance“S” (as shown schematically in FIG. 5) with respect to the target in an oscillating manner. Various positions of some of the drift paths are indicated by the dashed circles 511.

FIG. 7 exemplifies certain embodiments wherein the magnetic array assembly comprises a plurality of electron drift paths at least one of which has a generally or substantially circular configuration. In FIG. 7, the array assembly comprises a plurality of (i.e., at least two) drift paths that are at least generally circular. The illustrated arrangement here consists of drift paths that are at least generally circular, although this is not the case in other embodiments.

FIG. 7 is also representative of a group of embodiments wherein the magnetic array assembly when used creates at least two rows each comprising a plurality of (optionally at least three, or at least five, or even at least ten) drift paths having their respective centers spaced apart longitudinally. In some embodiments of this nature, the centers of corresponding drift paths of adjacent rows are offset longitudinally from one another (optionally by a least 0.125 inch, or at least about .5 inch, or at least about 1 inch, or even at least about 3 inches). For example, the first drift path (e.g., starting from a given end 30E of the target) of a first row is not at the same longitudinal locale as the first drift path of a second row. This may be the case for all corresponding drift paths of two or more rows, or only some of the corresponding drift paths may be so arranged. Moreover, it is by no means required to provide any offset of this nature when multiple rows are used.

FIG. 8 is a planar projection of a plurality of electron drift paths 510 formed by a magnetic array assembly 80 disposed in a cylindrical target 30 according to one embodiment of the invention.

The plurality of electron drift paths 510 in the exemplary embodiment of FIG. 8 comprises two rows (although one row, or more than two rows, of this nature can alternatively be provided) of electron drift paths 510 disposed along a length of a cylindrical target 30. Each row of electron drift paths 510 in FIG. 8 includes at least one generally oval electron drift path 510. FIG. 8 is representative of a group of embodiments wherein at least one of the rows (or each row) has a drift path that is at least generally or substantially circular, while at least one (and optionally a plurality of) other drift path in such row is generally oval shaped, irregularly shaped, or otherwise non-circular. In certain embodiments, a row may have as a last or first drift path (i.e., nearest one of the ends 30E of the target) a drift path that is at least generally or substantially circular. Another embodiment of this nature is shown in FIG. 10, as described below. The magnetic array assembly 80 associated with the embodiment of FIG. 8 can optionally be adapted to oscillate or otherwise move generally longitudinally with respect to the cylindrical target 30 to further promote uniform erosion of target material. Various positions of the turnarounds of some of the drift paths are indicated by the dashed semi-circles 512.

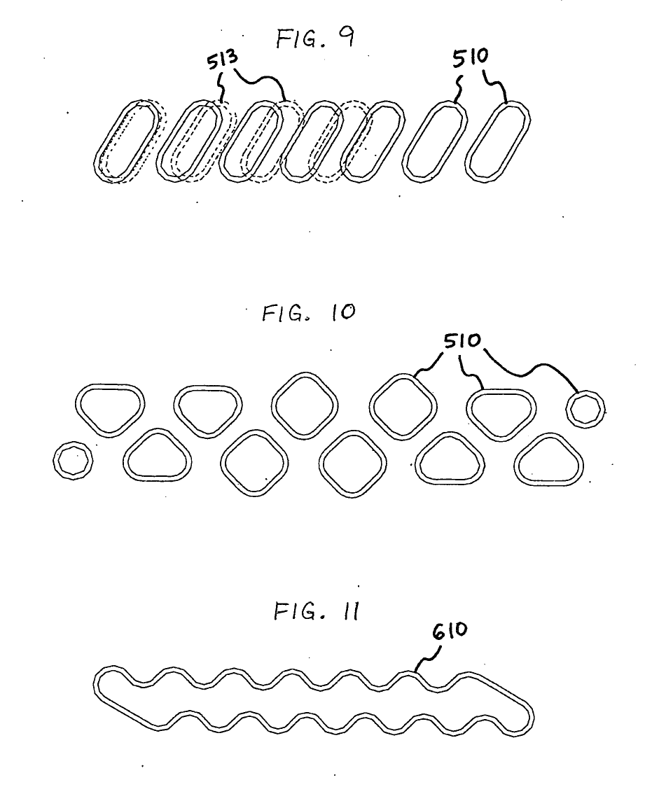

FIG. 9 is a planar projection of a plurality of electron drift paths 510 formed by a magnetic array assembly 80 disposed in a cylindrical target 30 according to one embodiment of the invention.

The plurality of electron drift paths 510 in the exemplary embodiment of FIG. 9 comprises a row of generally oval electron drift paths 510 disposed along a length of the cylindrical target 30.

The magnetic array assembly 80 associated with the embodiment of FIG. 9 can optionally be adapted to oscillate or otherwise move generally longitudinally with respect to the cylindrical target 30 to further promote uniform erosion of target material. Various positions of some of the drift paths are indicated by the dashed ovals 513.

FIG. 10 is a planar projection of a plurality of electron drift paths 510 formed by a magnetic array assembly 80 disposed in a cylindrical target 30 according to one embodiment of the invention. The plurality of electron drift paths 510 in the exemplary embodiment of FIG. 10 comprises two rows of electron drift paths 510 disposed along a length of a cylindrical target 30. Each row of electron drift paths 510 in FIG. 10 includes at least one generally circular electron drift path, at least one generally triangle-shaped electron drift path, and at least one generally rectangular or diamond-shaped electron drift path. The shapes illustrated in FIG. 10 and the other figures are not exhaustive of the possible shapes that can be used; other shapes can be selected by one of ordinary skill in the art with the benefit of these teachings. The magnetic array assembly 80 associated with the embodiment of FIG. 10 can optionally be adapted to oscillate or otherwise move generally longitudinally with respect to the cylindrical target 30 in order to further promote uniform erosion of target material.

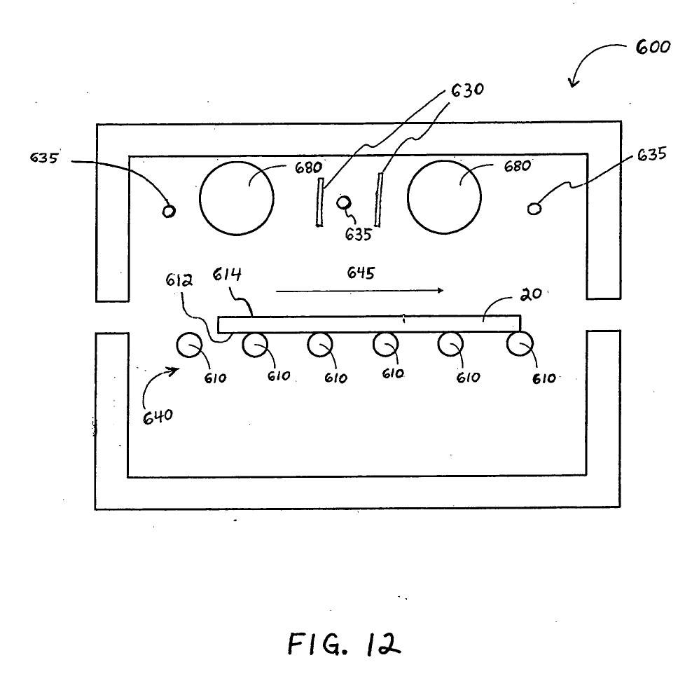

FIG. 11 is a planar projection of a generally serpentine-shaped electron drift path 610 formed by a magnetic array assembly 80 disposed in a cylindrical target 30 according to an embodiment of the invention. Here, the bends in the racetrack may serve to spread out, or even out, the effects normally associated with the turnarounds near the ends of the target, by providing frequent and periodic“mini” turnarounds substantially along the length of the target The magnetic array assembly 80 associated with the embodiment of FIG. 11 can optionally be adapted to oscillate or otherwise move generally longitudinally with respect to the cylindrical target 30 in order to promote uniform erosion of target material.

Certain embodiments of the invention provide for longitudinal movement (e.g., oscillation) of magnetic array assembly 80 within cylindrical target 30. The magnetic array assembly 80 can thus be movable in a generally axial direction (i.e., longitudinally) by about one-half centimeter or more, and desirably more than about one centimeter, such movement being preferred to substantially even out the target wear pattern 86 of a cathode target assembly 10. In some embodiments of the invention, the entire magnetic array 80 is adapted to move generally axially up to 4 centimeters or more. An example of an apparatus for providing oscillation of magnetic array assembly 80 is described in U.S. patent application Ser. No. 11/171,054 (filed Jun. 30, 2005, titled“Cylindrical Target With Oscillating Magnet For Magnetron Sputtering”), the entire contents of which are hereby incorporated by reference. Oscillators of this nature can be obtained commercially from General Plasma Inc. (Tucson, Arizona, USA). Thus, in certain method embodiments, a magnetic array assembly of the described nature is moved (e.g., in a back-and-forth manner) longitudinally during sputtering.

FIGS. 12-14 are cross-sectional side views of a deposition chamber which may be used to perform sputtering of target material in accordance with certain embodiments of the invention. In FIG. 12, the deposition chamber 600 comprises a substrate support 640 defining a path of substrate travel 645 extending through the deposition chamber. Preferably, the path of substrate travel 645 extends substantially horizontally through the deposition chamber 600. In the embodiments of FIGS. 12-14, the substrate support defines a path of substrate travel extending through the deposition chamber 600 between a chamber inlet and a chamber outlet.

Preferably, the substrate support 640 is configured for maintaining (e.g., supporting) the substrate 20 in a horizontal configuration while the substrate 20 is being coated (e.g., during conveyance of the substrate 20 through the deposition chamber 600). Thus, the support 640 desirably is adapted to convey a sheet-like substrate 20, and preferably multiple sheet-like substrates that are spaced-apart from one another, through the deposition chamber 600 while maintaining the/each substrate 20 in a horizontal orientation (e.g., wherein a top major surface 614 of the/each substrate 20 is upwardly oriented while a bottom major surface 612 of the/each substrate 20 is downwardly oriented). In the embodiments shown in the present figures, the substrate support 640 comprises a plurality of spaced-apart transport rollers 610. Typically, at least one of the rollers 610 is rotated (e.g., by energizing a motor operably connected to the roller) such that the substrate 20 is conveyed through the deposition chamber 600 along the path of substrate travel 645. When the substrate is conveyed over such rollers, the bottom surface 612 of the substrate 20 is in direct physical (i.e., supportive) contact with the rollers 610. The substrate 20 is typically conveyed through the deposition chamber 600 at a speed of about 100-500 inches per minute. In certain embodiments of the invention, the substrate 20 is a sheet of glass that is on the substrate support 640 during conveyance, and wherein other sheets of glass are also on the substrate support 640, such sheets of glass being spaced-apart from one another on the substrate support 640 and conveyed in such a spaced-apart configuration. While the illustrated substrate support 640 comprises a plurality of spaced-apart rollers 610, it is to be appreciated that other types of substrate supports can be used.

In certain embodiments, such as that illustrated in FIG. 12, the deposition chamber 600 comprises a downward coating configuration adapted for coating a top major surface 614 of the substrate 20. In such embodiments, the downward sputtering configuration comprises one or more upper targets 680 positioned above the path of substrate travel 645 through the deposition chamber 600. Additionally, the deposition chamber 600 can be provided with upper gas distribution pipes 635 (e.g., having outlets that are) positioned above the path of substrate travel 645. It will typically be preferred to also provide upper anodes 630 above the path of substrate travel 645. When provided, the upper anodes 630 are preferably positioned adjacent upper targets.

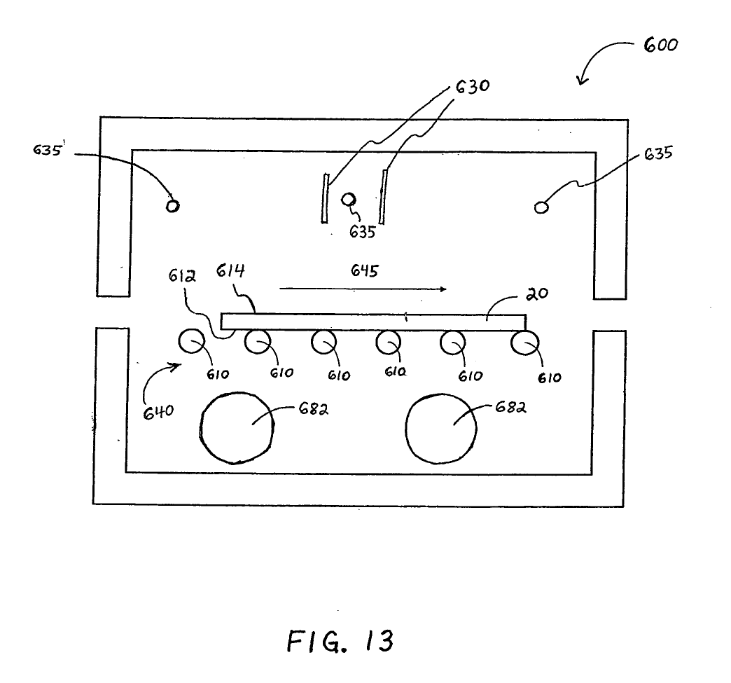

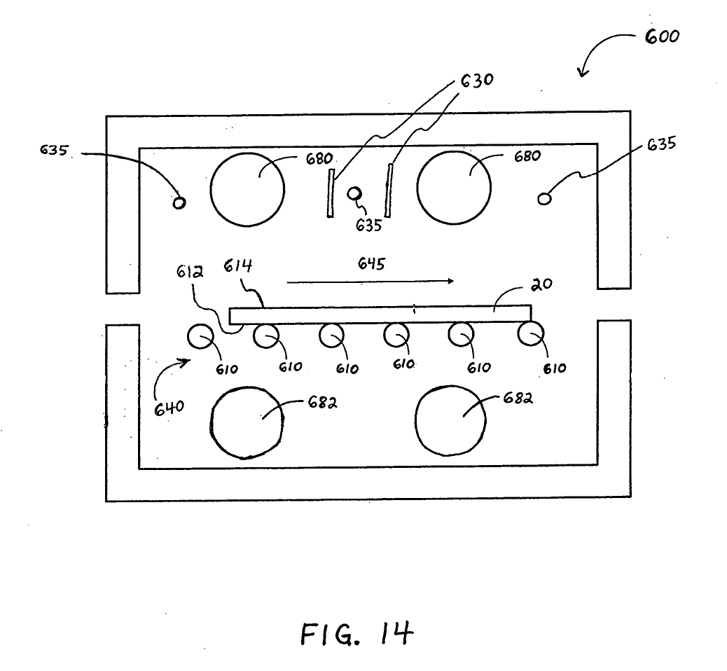

In certain embodiments, such as that illustrated in FIG. 13, the deposition chamber 600 comprises an upward coating configuration adapted for coating a bottom major surface 612 of the substrate 20. In such embodiments, the upward sputtering configuration comprises one or more lower targets 682 positioned beneath the path of substrate travel 645. Lower gas distribution pipes (not shown) may be used, and are typically positioned beneath the path of substrate travel 645. Similarly, optional lower anodes (not shown) can be positioned below the path of substrate travel 645. When provided, lower anodes are typically positioned adjacent the lower targets 682. Upward sputtering systems are described in U.S. patent applications Ser. Nos. 09/868,542, 09/868,543, 09/979,314, 09/572,766, and 09/599,301. FIG. 14 shows an embodiment of the invention in which both upper and lower targets 680, 682 are present to provide both upward and downward sputtering configurations. In the embodiments illustrated in FIGS. 12-14, the targets 680, 682 may be offset longitudinally from one another to further promote uniform sputtering/coating and even target depletion.

Thus, embodiments of a METHOD AND APPARATUS FOR CYLINDRICAL MAGNETRON SPUTTERING USING MULTIPLE ELECTRON DRIFT PATHS are disclosed. One skilled in the art will appreciate that the invention can be practiced with embodiments other than those disclosed. The disclosed embodiments are presented for purposes of illustration and not limitation, and the invention is limited only by the claims that follow.

What is claimed is:

1. A cathode target assembly for use in sputtering target material onto a substrate, comprising:
a generally cylindrical target having an axis, an inner portion, and an outer surface;
a motor to rotate the target about its axis during a sputtering operation;
a magnetic array disposed within the inner portion of the target, the array being adapted to generate a plasma confinement region adjacent the outer surface of the target, the plasma confinement region comprising magnetic and electric fields arranged to form at least one row of electron drift paths, said row comprising a plurality of electron drift paths having their respective centers spaced longitudinally from one another, said row extending along a substantial length of the target; and
a support device to support the magnetic array relative to the target.

2. The cathode target assembly of claim 1 wherein said row comprises at least three electron drift paths having their respective centers spaced longitudinally from one another.

3. The cathode target assembly of claim 1 wherein an electric field is formed by applying a voltage to the cathode target.

4. The cathode target assembly of claim 1 wherein the electron drift paths are formed by a vector cross product of the magnetic and electric fields.

5. The cathode target assembly of claim 1 wherein the magnetic array comprises:
a plurality of magnetic elements, each magnetic element comprising an inner portion having a first polarity, and an outer portion having a second polarity, the outer portion forming a loop around the inner portion such that a plurality of magnetic flux lines extend between the inner and outer portions,
wherein the magnetic elements provide a plurality of magnetic flux loops disposed along a length of the cylindrical target.

6. A magnetic array adapted for generating a plasma-containing confinement region near a cylindrical target during a sputtering operation, the magnetic array comprising:
a plurality of magnetic elements, each magnetic element having an inner portion having a first polarity, and an outer portion having a second polarity, the outer portion forming a loop around the inner portion such that a plurality of magnetic flux lines extend between the inner and outer portions,
wherein the magnetic elements are adapted to be disposed within the cylindrical target and operated to provide a plurality of magnetic flux loops disposed along a length of the cylindrical target.

7. The magnetic array of claim 6 wherein the magnetic flux loops are adapted to interact with an electric field to form a plurality of electron drift paths near a surface of the cylindrical target.

8. The magnetic array of claim 7 wherein the electron drift paths are spaced generally longitudinally along a length of the target.

9. The magnetic array of claim 7 wherein at least one of the electron drift paths is generally oval-shaped.

10. The magnetic array of claim 9 wherein said generally oval-shaped electron drift path is oriented at an oblique angle relative to the longitudinal axis of the target.

11. The magnetic array of claim 7 wherein the electron drift paths form a row of electron drift paths in which at least a portion of a desired one of the electron drift paths extends longitudinally beyond at least a portion of a neighboring electron drift path, said neighboring electron drift path being adjacent to said desired electron drift path.

12. The magnetic array of claim 11 wherein said neighboring electron drift path overlaps said desired electron drift path.

13. The magnetic array of claim 7 wherein the electron drift paths from at least two rows of electron drift paths, each row being oriented generally parallel to a longitudinal axis of the cylindrical target.

14. A magnetic element comprising
an inner portion having a first polarity, and
an outer portion having a second polarity, the outer portion forming a loop around the inner portion such that a plurality of magnetic flux lines extend between the inner and outer portions,
wherein the magnetic element is adapted to be mounted within a cylindrical target and operated to provide a generally serpentine-shaped magnetic flux loop extending along a substantial length of the cylindrical target.

15. A method of sputtering material from a cathode target assembly, the method comprising:
providing a deposition chamber for sputtering target material from a cathode target assembly onto a surface of a substrate;
providing a magnetic array within an inner portion of the cathode target assembly;
operating the magnetic array to form a plurality of plasma confinement regions along a substantial length of the cathode target assembly;
rotating the cathode target assembly relative to the magnetic array; and
moving the substrate relative to the cathode target assembly,
wherein the magnetic array comprises a plurality of magnetic elements having their respective centers spaced longitudinally from one another.

16. The method of claim 15 wherein each magnetic element comprises:
an inner portion having a first polarity, and
an outer portion having a second polarity opposite the first polarity, the outer portion forming a loop around the inner portion such that magnetic flux lines extend between the inner and outer portions to form a magnetic flux loop.

17. The method of claim 16 wherein the substrate is a large-area glass sheet.

18. The method of claim 16 further comprising causing the magnetic flux loops to interact with an electric field to form a plurality of electron drift paths near a surface of the cathode target assembly.

19. The method of claim 18 wherein at least one of the electron drift paths forms a generally oval-shaped pattern.

20. The method of claim 19 wherein the at least one generally oval-shaped electron drift path is oriented at an oblique angle relative to the longitudinal axis of the cathode target assembly.

21. The method of claim 18 wherein the electron drift paths form a row in which at least a portion of a desired one of the electron drift paths extends longitudinally beyond at least a portion of a neighboring electron drift path, said neighboring electron drift path being adjacent to said desired electron drift path.

22. The method of claim 21 wherein the desired electron drift path extends longitudinally beyond at least a portion of two neighboring electron drift paths adjacent to said desired electron drift path.

23. The method of claim 21 wherein said neighboring electron drift path overlaps said desired electron drift path.

24. The method of claim 18 further comprising forming at least two rows of electron drift paths, each row oriented generally parallel to a longitudinal axis of the cathode target assembly.

25. A method of sputtering material from a cathode target assembly, the method comprising:
providing a deposition chamber for sputtering target material from first and second generally cylindrical targets onto a surface of a substrate;
providing a first magnetic array within an inner portion of the first target;
operating the first magnetic array to form a plurality of plasma confinement regions along a substantial length of the first target;
supplying a reactive gas to the deposition chamber;
rotating the first target relative to the first magnetic array; and
moving the substrate relative to the first and second targets,
wherein the first magnetic array comprises a plurality of magnetic elements having their respective centers spaced longitudinally from one another along a substantial length of the first target.

26. The method of claim 25 further comprising:
providing a magnetic array within an inner portion of the second target;
operating the magnetic array to form a plurality of plasma confinement regions along a substantial length of the second target; and
rotating the second target relative to the magnetic array,
wherein the second magnetic array comprises a plurality of magnetic elements having their respective centers spaced longitudinally from one another along a substantial length of the second target.

27. The method of claim 25 wherein the first and second targets are offset longitudinally from one another.

28. The method of claim 25 further comprising arranging the first and second targets above a path of substrate travel through the deposition chamber and sputtering target material onto a top surface of the substrate.

29. The method of claim 28 further comprising providing at least a third target positioned below a path of substrate travel through the deposition chamber and sputtering target material onto a bottom surface of the substrate.

30. The method of claim 25 further comprising arranging the first and second targets below a path of substrate travel through the deposition chamber and sputtering target material onto a bottom surface of the substrate.

31. The method of claim 25 wherein each magnetic element comprises:
an inner portion having a first polarity; and
an outer portion having a second polarity opposite the first polarity, the outer portion forming a loop around the inner portion such that magnetic flux lines extend between the inner and outer portions to form a magnetic flux loop.

32. A method of sputtering material from a cathode target assembly, the method comprising:
providing a deposition chamber for sputtering target material from a cathode target assembly onto a surface of a substrate;
providing a magnetic array within an inner portion of the cathode target assembly;
operating the magnetic array to form a plurality of plasma confinement regions along a substantial length of the cathode target assembly;
rotating the cathode target assembly relative to the magnetic array; and
moving the substrate relative to the cathode target assembly,
wherein the magnetic array comprises a plurality of magnetic elements having their respective centers spaced longitudinally from one another, and wherein the plasma confinement regions comprise at least one row of electron drift paths.

33. The method of claim 32 wherein the at least one row of electron drift paths comprises at least five electron drift paths.

34. The method of claim 32 further comprising forming an electric field by applying a voltage to the cathode target assembly.

35. The method of claim 34 wherein each magnetic element comprises:
an inner portion having a first polarity; and
an outer portion having a second polarity opposite the first polarity, the outer portion forming a loop around the inner portion such that magnetic flux lines extend between the inner and outer portions to form a magnetic flux loop.

36. The method of claim 35 wherein an electron drift path is formed by an interaction between the electric field and a magnetic flux loop.
